(19) United States
(12) Patent Application Publication
(10) Pub. No.: US 2008/0143320 A1
(43) Pub. Date: Jun. 19, 2008

(54) Power Sensor with Switched-In Signal Amplification Path

(75) Inventor: Dean B. Nicholson, Windsor, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 11/553,478

(22) Filed: Oct. 27, 2006

(51) Int. Cl. G01R 31/00

(52) U.S. Cl. 324/96

(57) ABSTRACT

An RF power sensor is enclosed within a housing. An input port of the housing brings an RF signal into the housing. An RF switch within the housing switches the RF signal between an amplified path, a through path and an attenuated path. An RF power detector within the housing measures heat generated by the RF energy of the RF signal passing through the amplified path, through path or attenuated path.

### BACKGROUND OF THE INVENTION

The two most common types of power sensors can be classified as heat-based power sensors (also referred to as thermal-based power sensors) and rectification or diode-based sensors.

Thermal-based power sensors are true “averaging detectors” and include thermocouple and bolometer (thermistor or barretter) power sensors. They convert an unknown RF power to heat and detect that heat transfer. In other words they measure heat generated by the RF energy. These thermal sensors generally cannot provide accurate average power measurement capability if the noise floor is lower than approximately −30 to −35 dBm. Also, they generally only make accurate power measurements over a dynamic range of approximately 50 dB from approximately −30 dBm to +20 dBm.

Some prior-art diode-based sensors have a dynamic range of 80 dB, but can not measure the average power of modulated signals as accurately as thermal-based power sensors.

Signal analyzers can provide average power measurements with lower noise floors than the prior-art thermal-based power sensors, but only with extensive software corrections, less accuracy and at much greater cost.

It would be desirable to maintain the accurate average power measurement capability of the prior art prior-art thermal-based sensors while extending the noise floor down to at least −50 dBm or −60 dBm.

### SUMMARY OF THE INVENTION

The present invention provides a thermal-based power sensor with switched-in signal amplification path having a noise floor extending down to at least −50 dBm or −60 dBm and covering a dynamic range of at least 70 dB from approximately −50 dBm to +20 dBm or more.

In more general terms the invention is an RF thermal-based power sensor including an enclosing housing. An input port of the housing brings an RF signal into the housing. An RF switch within the housing switches the RF signal between an amplified path, a through path and an attenuated path. An RF thermal-based power detector within the housing measures heat generated by the RF energy of the RF signal passing through the amplified path, through path or attenuated path.

### BRIEF DESCRIPTION OF THE DRAWINGS

Further preferred features of the invention will now be described for the sake of example only with reference to the following figure, in which:

FIG. 1 shows the power sensor with switched-in signal amplification path of the present invention.

### DETAILED DESCRIPTION

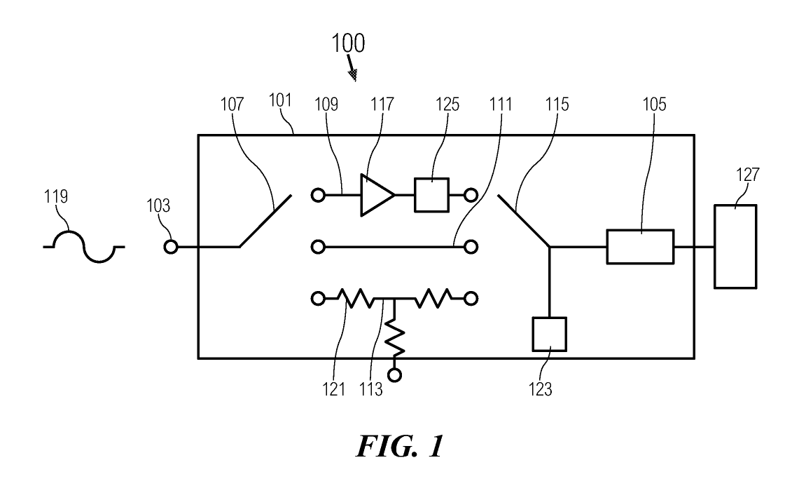

FIG. 1 shows an RF power sensor 100 which includes an enclosing housing 101. An input port 103 of the housing brings an RF signal 119 into the housing. The RF frequency range is considered to cover frequencies from approximately 150 kHz up to the IR range, though recent improvements in DC blocking capacitors have allowed these RF techniques to be extended down to below 10 kHz in many applications. In other embodiments the frequency can be limited to the microwave frequency range of 1 GHz and higher or the frequency can be limited to the optical range. The transmission media used can be cable, waveguide, or other media.

An RF power detector 105 is within the housing 101. The RF power detector 105 can be a thermal-based power detector serving as a true “averaging detector” and can be, for example a thermocouple detector, a thermistor detector or a barretter detector. The thermal-based power detectors convert an unknown RF power to heat and detect the heat transfer. In other words they measure heat generated by the RF energy. Other types of average power measurement detectors can also be used.

Within the housing 101 of the RF power sensor 100 are three different paths through which the RF signal 119 can travel to the RF power detector 105.

The three paths are an amplified path 109 including a solid-state amplifier 117 through which the RF signal 119 is amplified and passed to the RF power detector 105, a through path 111 through which the RF signal 119 is passed to the RF power detector 105, and an attenuation path 113 including an RF attenuator 121 through which the RF signal 119 is attenuated and passed to the RF power detector 105.

The amplified path 109 can include one or more solid-state amplifiers 117 for amplifying the RF signal 119. In other embodiments the amplifiers 117 can be of types other than solid-state amplifiers. The amplifier 117 can have it's gain calibrated and corrected over frequency and temperature to maintain accuracy.

A first switch 107 is also within the housing 101. The switch has three separate positions corresponding to the three different paths 109, 111, 113 through which the RF signal 119 can travel.

A second switch 115 is within the housing 101 and also has three separate positions corresponding to the three different paths through which the RF signal 119 can travel.

The first and second switches 107, 115 are in a first position wherein they direct the RF signal 119 through the first amplified path 109 when the RF signal has a low power level of less than approximately −50 dBm.

The first and second switches 107, 115 are in a second position wherein they direct the RF signal 119 through the second through path 111 when the RF signal has a medium power level of between approximately −50 dBm and +30 dBm.

The first and second switches 107, 115 are in a third position wherein they direct the RF signal 119 through the third attenuation path 113 including an RF attenuator 121 when the RF signal has a power level of greater than approximately +30 dBm.

Thus the power sensor measures an average power of the RF signal received by the input port over a dynamic range of more than approximately 80 dB.

The first and second switches 107, 115 can be many different types of switches such as MEMS switches or solid state switches. Preferably the switch is a switch with low distortion.

The switch 115 is under the control of a processor 123 which can be part of the RF power sensor 100 or can be part of a power meter 127, for example. The control of the switching to determine which path 109, 111, 113 is selected for the RF signal 119 to go through can be made, for example, by the power meter 127 following the sensor using the processor 123. The power meter 127 knows the present path selected and the present power level being read, and can determine if the present selected path is the proper one for the measurement, or if a different path should be selected. As an example, if the attenuated path 113 has been selected, and no RF signal, or an RF signal near the noise floor of the sensor is being read, then the power meter 127 changes the switches to configure the measurement to be made with the thru path 111. If the new power meter reading with the thru path 111 is still at or near the noise floor of the sensor, then the power meter 127 would reconfigure the sensor switches to select the amplified and filtered path 109. Extensions and further examples of this technique for selecting how to control the switches for the power sensor are straightforward, and will not be given here.

The amplified path 109 amplifies the low power signal 119 so that it is at a level detectable by the RF power detector 105. This amplification improves the noise floor of the of the RF power detector 105 because the noise floor is determined by the thermal noise effects of the RF power detector 105 rather than by the noise power for the RF power detector 105.

The noise power (Pn) is:

Pn=k*T*BW

where Pn is power in watts, k is Boltzmann's constant (1.38×10⁻²³ J/K), T is the temperature in Kelvin (K) and BW is the bandwidth in Hertz. In the RF power detector 105, the bandwidth BW can be 20 GHz.

The result for the noise power is Pn=−71 dBm at a temperature of 290 K.

The noise floor of current thermal-based power detectors, such as thermocouple or thermistor detectors, is approximately −30 to −35 dBm. Therefore the detector noise floor is not set by the noise power of −71 dBm, but rather it is set by the power level of a signal needed to raise the temperature of the measuring thermal-based power detector above the level of thermal noise.

Thus, approximately 30 dB of gain can be switched in using the switches 107, 115 to switch in one or more of the amplifiers 117. This amplifier gain will increase the noise power by 30 dB from approximately −71 dBm to approximately −40 dBm. This will have no impact on the sensor noise floor which is set by the thermal effects to approximately −30 dBm, and so is still 10 dB above the noise floor set by the RF noise integrated over frequency. With 30 dB of gain, even a signal 119 with a power level of −50 dBm or less will be amplified to 10 dB higher than the thermal noise floor of the sensor, allowing for fast and accurate measurement.

In the foregoing specification, the invention has been described with reference to specific exemplary embodiments thereof. The specification and drawings are, accordingly, to be regarded in an illustrative sense rather than a restrictive sense.

1. An RF thermal-based power sensor including an enclosing housing comprising:
an input port of the housing for bringing an RF signal into the housing;
an RF thermal-based power detector within the housing;
a first switch within the housing, which switches between a first position when the RF signal has a power level of less than approximately −50 dBm, a second position when the RF signal has a power level of between approximately −50 dBm and +30 dBm and a third position when the RF signal has a power level of greater than approximately +30 dBm;
a second switch within the housing which switches between a first position, a second position and a third position;
an amplified path including a solid-state amplifier through which the RF signal is amplified and passed to the RF power detector when the first and second switches are in the first positions;
a through path through which the RF signal is passed to the RF power detector when the first and second switches are in the second positions; and
an attenuation path including an RF attenuator through which the RF signal is attenuated and passed to the RF power detector when the first and second switches are in the third positions.

2. An RF power sensor comprising:
a housing;
an input port of the housing for bringing an RF signal into the housing;
an RF switch within the housing for switching the RF signal between an amplified path and a non-amplified path; and
an RF power detector within the housing for measuring RF power output from the amplified path.

3. The power sensor of claim 2, wherein the RF power detector is a thermocouple detector.

4. The power sensor of claim 2, wherein the RF power detector is a thermistor detector.

5. The power sensor of claim 2, further comprising a second switch for switching between the amplified path to direct an amplified RF signal to the RF power detector and the non-amplified path to direct a non-amplified signal to the RF power detector.

6. The power sensor of claim 2, wherein the amplified path includes a solid-state amplifier.

7. The power sensor of claim 6, wherein the solid-state amplifier has a gain of approximately +30 dB.

8. The power sensor of claim 2, wherein the non-amplified path is an attenuator path including an RF attenuator.

9. The power sensor of claim 5, further comprising an attenuator path including an RF attenuator and wherein the non-amplified path is a through path.

10. The power sensor of claim 9, wherein the second switch is for switching between the amplified path, through path and attenuator path.

11. The power sensor of claim 2, wherein the power sensor measures an average power of the RF signal received by the input port over a dynamic range of at least 80 dB.

12. The power sensor of claim 2, wherein the power sensor measures an average power of the RF signal received by the input port.

13. The power sensor of claim 10, wherein the RF switch within the housing switches the RF signal to the amplified path when the RF signal received by the input port has a power level of less than approximately −50 dBm.

14. The power sensor of claim 10, wherein the RF switch within the housing switches the RF signal to the through path when the RF signal received by the input port has a power level of between approximately −50 dBm and +30 dBm.

15. The power sensor of claim 10, wherein the RF switch within the housing switches the RF signal to the attenuator path when the RF signal received by the input port has a power level greater than approximately +30 dBm.

16. The power sensor of claim 2, wherein the RF switch is a MEMS switch.

17. The power sensor of claim 2, wherein the RF switch is a solid state switch.

18. The power sensor of claim 2, wherein the amplified path is within the housing and includes a solid-state amplifier also within the housing.

19. The power sensor of claim 10, wherein the second switch, the amplified path, the through path and attenuator path are all within the housing and the amplified path includes a solid-state amplifier also within the housing.

20. The power sensor of claim 2, wherein the RF power detector an RF thermal-based power detector.
